(19) United States
(12) Patent Application Publication
(10) Pub. No.: US 2024/0425987 A1
(43) Pub. Date: Dec. 26, 2024

(54) SHOWERHEAD ASSEMBLY AND SHOWERHEAD PLATE

(71) Applicant: ASM IP Holding B.V., Almere (NL)

(72) Inventors: Qi Qi, Phoenix, AZ (US); Rajmohan Muthaiah, Phoenix, AZ (US); Shubham Garg, Gilbert, AZ (US); Jaebeom Lee, Tempe, AZ (US); YoungChol Byun, Tempe, AZ (US); Daniel Maurice, Phoenix, AZ (US); Nirmal Gokuldas Waykole, Tempe, AZ (US); Jiyeon Kim, Mesa, AZ (US); Jacqueline Wrench, Mesa, AZ (US); Neelam Sheoran, Tempe, AZ (US); Guannan Chen, Phoenix, AZ (US)

(21) Appl. No.: 18/746,191

(22) Filed: Jun. 18, 2024

Related U.S. Application Data
(60) Provisional application No. 63/522,976, filed on Jun. 23, 2023.

(51) Int. Cl. C23C 16/455

(52) U.S. Cl. CPC C23C 16/45565; C23C 16/4558

(57) ABSTRACT

Various embodiments of the present technology may provide a showerhead assembly that includes a showerhead plate having a plurality of through-holes. Each through-hole has a conical-shaped inlet and a conical-shaped outlet. The showerhead plate may include through-holes in a center region having first dimensions and through-holes in an outer region having second dimensions that are different from the first dimensions.

### CROSS-REFERENCE TO RELATED APPLICATIONS

This application is a nonprovisional of, and claims priority to and the benefit of, U.S. Provisional Patent Application No. 63/522,976, filed Jun. 23, 2023 and entitled “SHOWERHEAD ASSEMBLY AND SHOWERHEAD PLATE,” which is hereby incorporated by reference herein.

### FIELD OF INVENTION

The present disclosure generally relates to a showerhead assembly and showerhead plate. More particularly, the present disclosure relates to a showerhead plate used in a semiconductor manufacturing tool.

### BACKGROUND OF THE TECHNOLOGY

A showerhead assembly may be used during a deposition process to provide uniform gas flow onto a wafer. However, due to the arrangement of the through-holes in the showerhead plate and varying velocities of the gas flow, wafer non-uniformity may occur. In particular, the area at the center of the wafer may exhibit varying thickness relative to the outer edges of the wafer.

### SUMMARY OF THE INVENTION

Various embodiments of the present technology may provide a showerhead assembly that includes a showerhead plate having a plurality of through-holes. Each through-hole has a conical-shaped inlet and a conical-shaped outlet. The showerhead plate may include through-holes in a center region having first dimensions and through-holes in an outer region having second dimensions that are different from the first dimensions.

According to one aspect, a showerhead plate comprises: a top surface and an opposing bottom surface; a center region located at a geometric center of the showerhead plate, wherein the center region has a diameter in a range of 10 mm to 60 mm; an outer region surrounding the center region and extending toward an outer edge of the showerhead plate; a plurality of first through-holes located within the center region and extending from the top surface to the bottom surface; a plurality of second through-holes located within the outer region and extending from the top surface to the bottom surface; wherein the second through-holes are differently-shaped from the first through-holes.

In one embodiment of the showerhead plate, each second through-hole comprises a conical-shaped inlet, having first dimensions, at the top surface and a conical-shaped outlet, having the first dimensions, at the bottom surface, and a linear channel connecting the inlet to the outlet.

In one embodiment of the showerhead plate, the linear channel has a length in a range of 11 mm to 17 mm and a diameter in a range of 0.5 mm to 1.5 mm, and the conical-shaped inlet and outlet have a maximum diameter in a range of 8 mm to 9 mm.

In one embodiment of the showerhead plate, each first through-hole comprises a first conical-shaped inlet, having first dimensions, at the top surface and a second conical-shaped outlet, having the second dimensions, at the bottom surface, and a linear channel connecting the inlet to the outlet, wherein the first dimensions are different from the second dimensions.

In one embodiment of the showerhead plate, the linear channel has a length in a range of 4 mm to 6 mm and a diameter in a range of 0.5 mm to 1.5 mm, and the conical-shaped inlet and outlet have a maximum diameter in a range of 8 mm to 9 mm.

In one embodiment of the showerhead plate, the linear channel has a length in a range of 8 mm to 11 mm and a diameter in a range of 0.5 mm to 1.5 mm, and the conical-shaped inlet and outlet have a maximum diameter in a range of 8 mm to 9 mm.

In one embodiment of the showerhead plate, the linear channel has a length in a range of 4 mm to 6 mm and a diameter in a range of 0.5 mm to 1.5 mm, and the conical-shaped inlet and outlet have a maximum diameter in a range of 8 mm to 9 mm.

In one embodiment of the showerhead plate, the linear channel has a length in a range of 4 mm to 6 mm and a diameter in a range of 0.5 mm to 1.5 mm, and the conical-shaped inlet has a first maximum diameter and outlet has a second maximum diameter, wherein the second maximum diameter is larger than the first maximum diameter.

In one embodiment of the showerhead plate, the plurality of first holes has a number of first holes in a range of 18 to 20.

In one embodiment of the showerhead plate, the plurality of first holes has a number of first holes in a range of 28-32.

According to another aspect, a showerhead plate comprises: a top surface and an opposing, bottom surface; a center region located at a geometric center of the showerhead plate, wherein the center region has a diameter in a range of 10 mm to 60 mm; an outer region surrounding the center region and extending to an outer edge of the showerhead plate; a plurality of first through-holes located within the center region and extending from the top surface to the bottom surface, wherein each first through-hole comprises: a first inlet having a first conical shape and first dimensions, at the top surface; a first outlet having a second conical shaped and second dimensions, at the bottom surface; and a first linear channel connecting the first inlet to the first outlet; wherein the first dimensions are different from the second dimensions; a plurality of second through-holes located within the outer region and extending from the top surface to the bottom surface, wherein each second through-hole comprises: a second inlet having the first conical shape and first dimensions, at the top surface; a second outlet having the first conical shape and first dimensions, at the bottom surface; and a second linear channel connecting the second inlet to the second outlet.

In one embodiment of the showerhead plate, the second linear channel has a length in a range of 11 mm to 17 mm and a diameter in a range of 0.5 mm to 1.5 mm, and the second inlet and the second outlet each have a maximum diameter in a range of 8 mm to 9 mm.

In one embodiment of the showerhead plate, the first linear channel has a length in a range of 4 mm to 6 mm and a diameter in a range of 0.5 mm to 1.5 mm, and the first inlet and the first outlet each have a maximum diameter in a range of 8 mm to 9 mm.

In one embodiment of the showerhead plate, the first linear channel has a length in a range of 8 mm to 11 mm and a diameter in a range of 0.5 mm to 1.5 mm, and the first inlet and the first outlet each have a maximum diameter in a range of 8 mm to 9 mm.

In one embodiment of the showerhead plate, the first linear channel has a length in a range of 4 mm to 6 mm and a diameter in a range of 0.5 mm to 1.5 mm, and the first inlet and the first outlet have a maximum diameter in a range of 8 mm to 9 mm.

In one embodiment of the showerhead plate, the first linear channel has a length in a range of 4 mm to 6 mm and a diameter in a range of 0.5 mm to 1.5 mm, and the conical-shaped inlet has a first maximum diameter and outlet has a second maximum diameter, wherein the second maximum diameter is larger than the first maximum diameter.

In one embodiment of the showerhead plate, the plurality of first holes has a number of first holes in a range of 18 to 32.

According to another aspect, a showerhead assembly comprises: a lid comprising a main inlet configured to couple to a gas source; a plenum space in communication with the main inlet and defined at least in part by the lid and a showerhead plate, wherein the showerhead plate comprises: a top surface and an opposing, bottom surface; a center region located at a geometric center of the showerhead plate, wherein the center region has a diameter in a range of 10 mm to 60 mm; an outer region surrounding the center region and extending to an outer edge of the showerhead plate; a plurality of first through-holes located within the center region and extending from the top surface to the bottom surface, wherein each of the first through-holes comprises: a conical-shaped first inlet; a conical-shaped first outlet; and a first linear channel connecting the inlet and the outlet; and a plurality of second through-holes located within the outer region and extending from the top surface to the bottom surface, wherein each of the second through-holes comprises: a conical-shaped second inlet; a conical-shaped second outlet, wherein the second inlet and the second outlet have equal conical dimensions; and a second linear channel connecting the inlet and the outlet; wherein the second through-holes are differently-shaped from the first through-holes; and wherein the second linear channel has a length that is greater than a length of the first linear channel.

The reaction chamber according to claim 18, wherein the plurality of first holes has a number of first holes in a range of 18 to 32.

The reaction chamber according to claim 18, wherein the first linear channel has a length in a range of 4 mm to 12 mm and the second linear channel has a length in a range of 12 mm to 20 mm.

According to yet another aspect, A showerhead assembly, comprising: a lid comprising a main inlet configured to couple to a gas source; a plenum space in communication with the main inlet and defined at least in part by the lid and a showerhead plate, wherein the showerhead plate comprises: a top surface and an opposing, bottom surface; a center region located at a geometric center of the showerhead plate, wherein the center region has a diameter in a range of 10 mm to 60 mm; an outer region surrounding the center region and extending to an outer edge of the showerhead plate; a plurality of first through-holes located within the center region and extending from the top surface to the bottom surface, wherein at least one hole from the plurality of first through-holes comprises an angled channel extending from a first inlet at the top surface to a conical-shaped first outlet at the bottom surface; and a plurality of second through-holes located within the outer region and extending from the top surface to the bottom surface, wherein each of the second through-holes comprises: a conical-shaped second inlet; a conical-shaped second outlet, wherein the second inlet and the second outlet have equal conical dimensions; and a second linear channel connecting the inlet and the outlet; wherein the second through-holes are differently-shaped from the first through-holes.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a block diagram in accordance with various embodiments of the present technology;

FIG. 2 representatively illustrates a reactor in accordance with various embodiments of the present technology;

FIG. 3 illustrates a top view of a showerhead plate in accordance with various embodiments of the present technology;

FIG. 4 illustrates an isometric view of a portion of the showerhead plate in accordance with embodiments of the present technology;

FIG. 5 illustrates a cross-sectional view of a center region of the showerhead plate in accordance with various embodiments of the present technology;

FIG. 6 illustrates a cross-sectional view of a center region of the showerhead plate in accordance with an embodiment of the present technology;

FIG. 7 illustrates a cross-sectional view of a center region of the showerhead plate in accordance with an alternative embodiment of the present technology;

FIG. 8 illustrates a cross-sectional view of a center region of the showerhead plate in accordance with an alternative embodiment of the present technology;

FIG. 9 illustrates a top-view of a center region of a showerhead plate in accordance with an alternative embodiment of the present technology;

FIG. 10 illustrates a cross-sectional view of a center region of a showerhead plate in accordance with the embodiment of FIG. 9;

FIG. 11 illustrates a cross-sectional view of a center region of a showerhead plate in accordance with the embodiment of FIG. 9; and

FIG. 12 illustrates a view of a bottom surface of a showerhead plate in accordance with the embodiment of FIG. 9.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, susceptors, valves, precursors, and delivery lines.

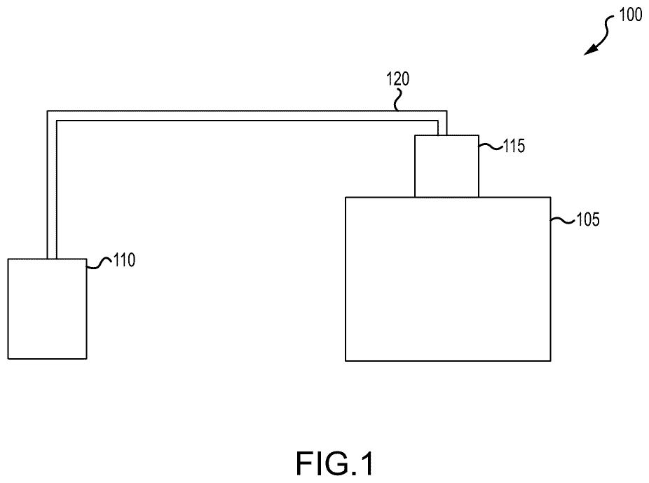

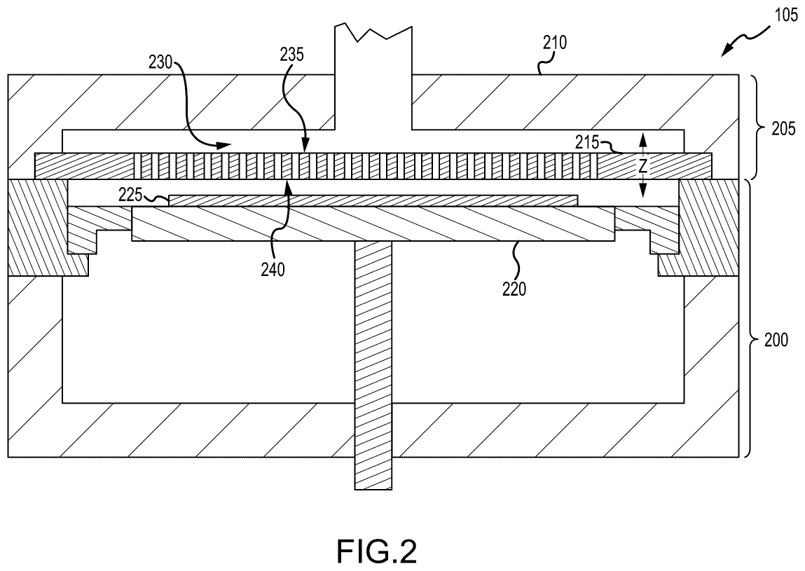

Referring to FIG. 1, an exemplary system 100 may comprise a reactor 105 configured to process a substrate (e.g., a wafer 225, FIG. 2). For example, the reactor 105 may be configured to deposit a film on the wafer, perform etching, and the like. The system 100 may further a source vessel 110 configured to contain or hold a chemistry (e.g., a precursor or a reactant) used in a semiconductor manufacturing process. The chemistry in the source vessel 110 may be in a solid, liquid, or gas phase initially. In the case of a solid or a liquid chemistry, the solid or liquid may be converted to a gas phase. For example, the source vessel 110 may comprise various devices and/or systems to convert a solid or a liquid to a gas. The conversion to a gas phase may occur within the source vessel 110. In addition, the system 100 may further comprise a gas line 120 to transport the gas to the reactor 105. For example, the gas line 120 may be coupled to the source vessel 110 at a first end and the reactor 105 at a second end. In various embodiments, the system 100 may further comprise a valve manifold 115 configured to provide mixing of multiple gas sources prior to entry into the reactor 105. The valve manifold 115 may be coupled directly to the reactor 105 and may be coupled to the gas line 120 and configured to receive the gas from the source vessel 110.

Referring to FIG. 2, the reactor 105 may comprise a reaction chamber 200 and a showerhead assembly 205. The reaction chamber 200 may comprise a susceptor 220 configured to support the wafer 225.

In various embodiments, the showerhead assembly 205 may positioned above the reaction chamber 200. In an exemplary embodiment, the showerhead assembly 205 may comprise a lid 210 and a showerhead plate 215. The showerhead assembly 205 may further comprise a plenum space 230 defined by the lid 210 and the showerhead plate 215. The lid 210 may comprise a main inlet configured to allow gas from the gas line 120 or valve manifold 115 to enter a plenum space 230.

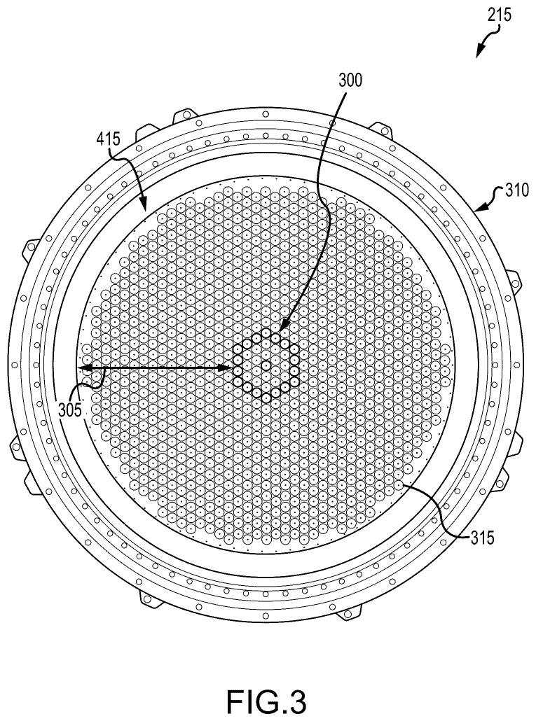

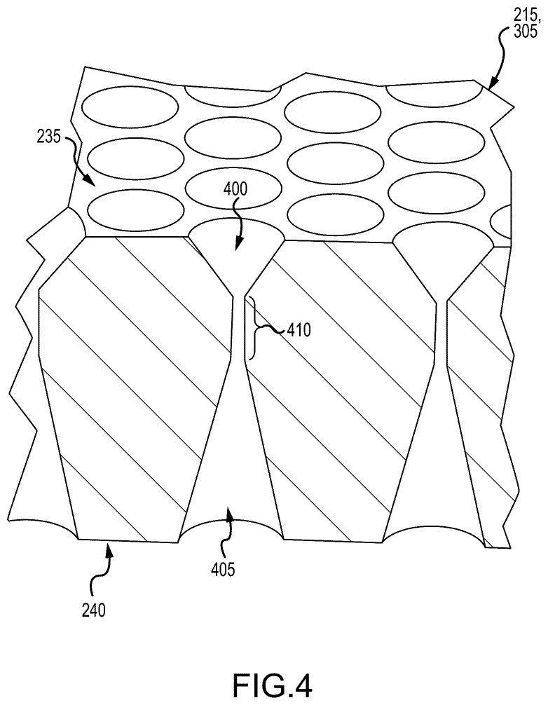

The showerhead plate 215 may be positioned above the susceptor 220 or wafer 225 and may be configured to allow gas to pass through it and into the reaction chamber 200. For example, and referring to FIGS. 3 and 4, the showerhead assembly 205 may comprise a plurality of through-holes 315 extending from a first surface 235 (e.g. a top surface) of the showerhead plate 215 to an opposing, second surface 240 (e.g., a bottom surface) of the showerhead plate 215. Each through-hole may be configured to allow gas to flow from through the showerhead plate 215—i.e., from the top surface 235 to the bottom surface 240. In various embodiments, the showerhead plate 215 may have a total thickness T in the range of 20 to 30 mm.

In an exemplary embodiment, and referring to FIG. 3, the showerhead plate 215 may comprise a center region 300 located at a geometric center of the showerhead plate 215. The showerhead plate 215 may further comprise an outer region 305 surrounding the center region 300 and extending toward an outer edge 310 of the showerhead plate 215. In various embodiments, the center region 300 may comprise a plurality of first through-holes having first dimensions and the outer region 305 may comprise a plurality of second through-holes having second dimensions, wherein the first through-holes are differently-dimensioned from the second through-holes.

In various embodiments, and referring to FIGS. 4-8, each through-hole 315 from the plurality of first through-holes and the plurality of second through-holes may comprise an inlet 400 having a conical shape and an outlet 405 having a conical shape. Each through-hole 315 may further comprise a linear channel 410 connecting the inlet 400 to the outlet 405. The linear channel 410 may have a uniform diameter. In an exemplary embodiment, the diameter of the linear channel 410 may be in a range of 0.8 mm to 1.5 mm. In an exemplary embodiment, the diameter of the linear channel 410 is 1 mm. In addition, the linear channel 410 may be parallel to a vertical axis Z of the showerhead plate 215.

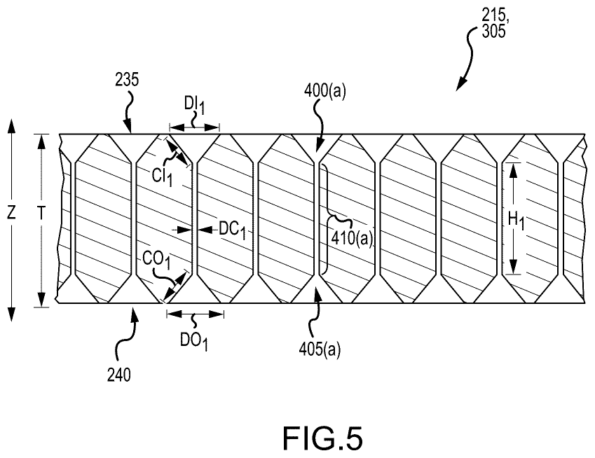

Referring to FIG. 5, each through-hole from the plurality of second through-holes comprises an inlet 400(a) with a maximum diameter DI₁ in a range of 8 mm to 9 mm and an outlet 405(a) with a maximum diameter DO₁ in a range of 8 mm to 9 mm. Each through-hole may further comprise a linear channel 410(a) with a height h₁ in a range of 11 mm to 17 mm and a diameter DC₁ in a range of 0.5 mm to 1.5 mm. Further, the inlet conical shape is the same as the outlet conical shape. In particular, a slant height CI₁ of the conical-shaped inlet 400(a) is the same as the slant height CO₁ of the conical-shaped outlet 405(a).

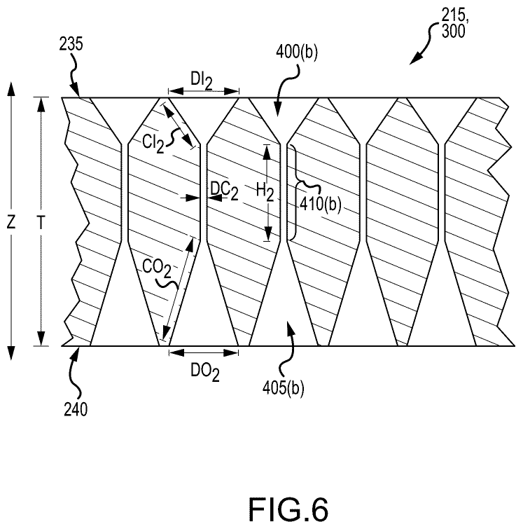

In one embodiment, and referring to FIG. 6, each through-hole from the plurality of first through-holes may comprise an inlet 400(b) with a maximum diameter DI₂ in a range of 8 mm to 9 mm and an outlet 405(b) with a maximum diameter DO₂ in a range of 8 mm to 9 mm. In particular, DI₂ is equal to DO₂. Each through-hole according to the present embodiment may further comprise a linear channel 410(b) with a height H₂ in a range of 8 mm to 11 mm and a diameter DC₂ in a range of 0.5 mm to 1.5 mm. Further, the inlet conical shape is different from the outlet conical shape. In particular, a slant height CI₂ of the conical-shaped inlet 400(b) is less than a slant height CO₂ of the conical-shaped outlet 405(b). The slant height CI₂ may be equal to the slant height CI₁. In the present embodiment, the center region 300 may comprise 31 through-holes 400(b).

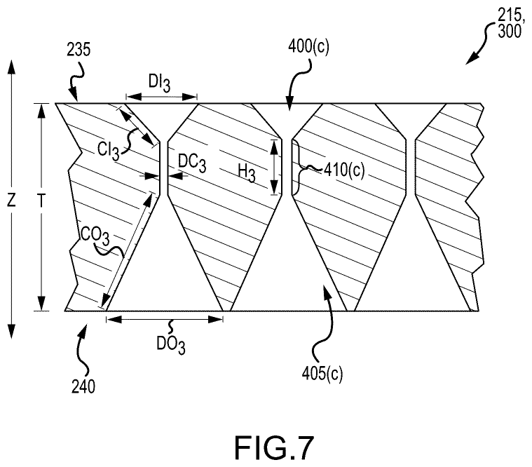

In another embodiment, and referring to FIG. 7, each through-hole from the plurality of first through-holes may comprise an inlet 400(c) with a maximum diameter DI₃ in a range of 8 mm to 9 mm and an outlet 405(c) with a maximum diameter DO₃ in a range of 12 mm to 15 mm. Each through-hole according to the present embodiment may further comprise a linear channel 410(c) with a height H₃ in a range of 4 mm to 6 mm and a diameter DC₃ in a range of 0.5 mm to 1.5 mm. Further, the inlet conical shape is different from the outlet conical shape. In particular, a slant height CI₃ of the conical-shaped inlet 400(c) is less than a slant height CO₃ of the conical-shaped outlet 405(c). The slant height CI₃ of the inlet 400(c) may be equal to the slant height CI₁ of the inlet 400(a). In the present embodiment, the center region 300 may comprise 19 through-holes 400(c).

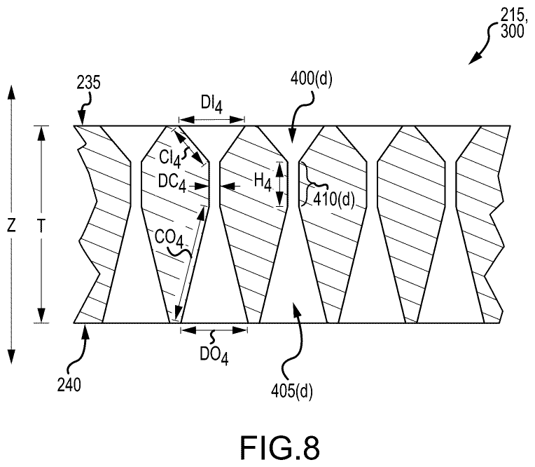

In another embodiment, and referring to FIG. 8, each through-hole from the plurality of first through-holes may comprise an inlet 400(d) with a maximum diameter DI₄ in a range of 8 mm to 9 mm and an outlet 405(d) with a maximum diameter DO₄ in a range of 8 mm to 9 mm. In particular, DI₄ is equal to DO₄. Each through-hole according to the present embodiment may further comprise a linear channel 410(d) with a height H₄ in a range of 4 mm to 6 mm and a diameter DC₄ in a range of 0.5 mm to 1.5 mm. Further, the inlet conical shape is different from the outlet conical shape. In particular, a slant height CI₄ of the conical-shaped inlet 400(d) is less than a slant height CO₄ of the conical-shaped outlet 405(d). The slant height CI₄ of the inlet 400(d) may be equal to the slant height Chi of the inlet 400(a). In the present embodiment, the center region 300 may comprise 31 through-holes 400(d).

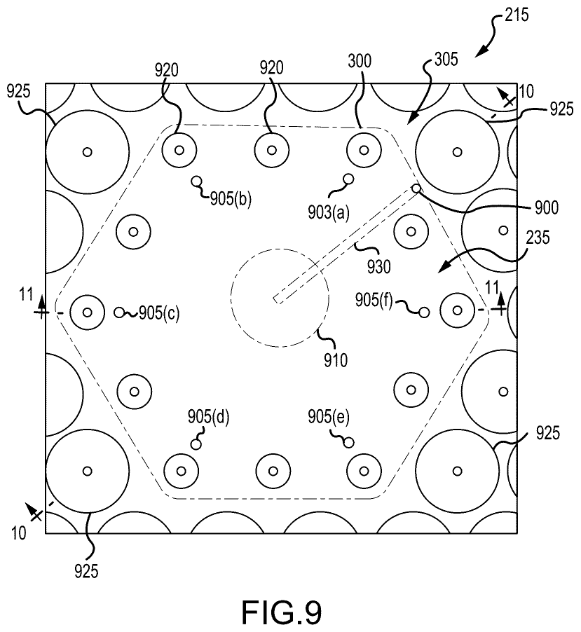

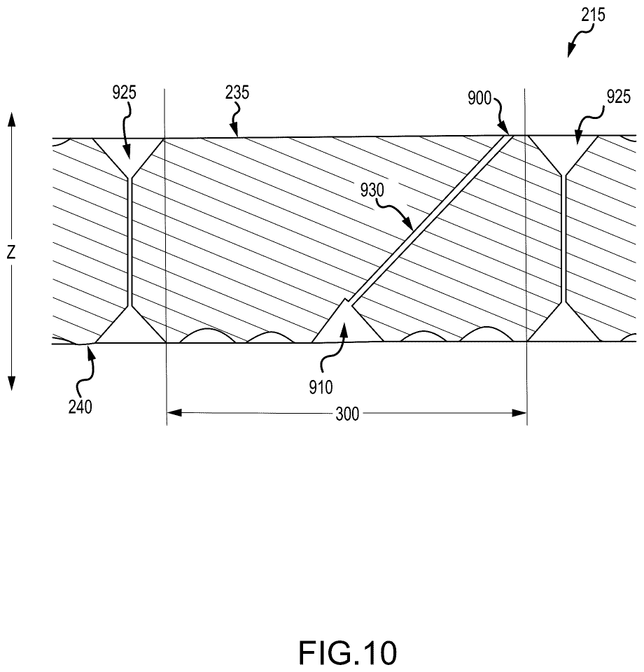

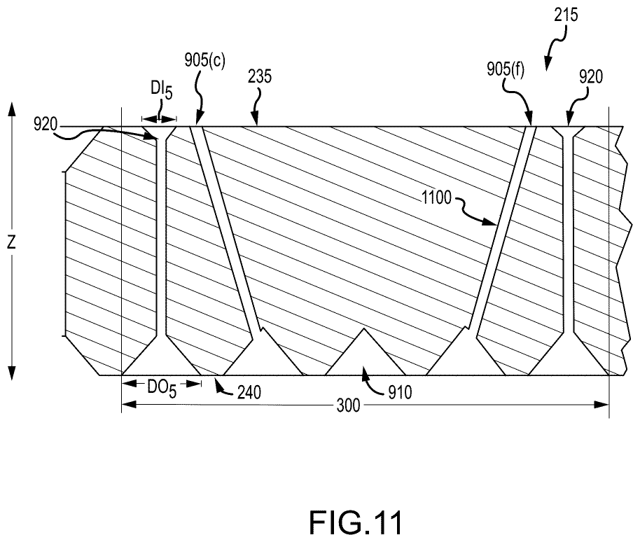

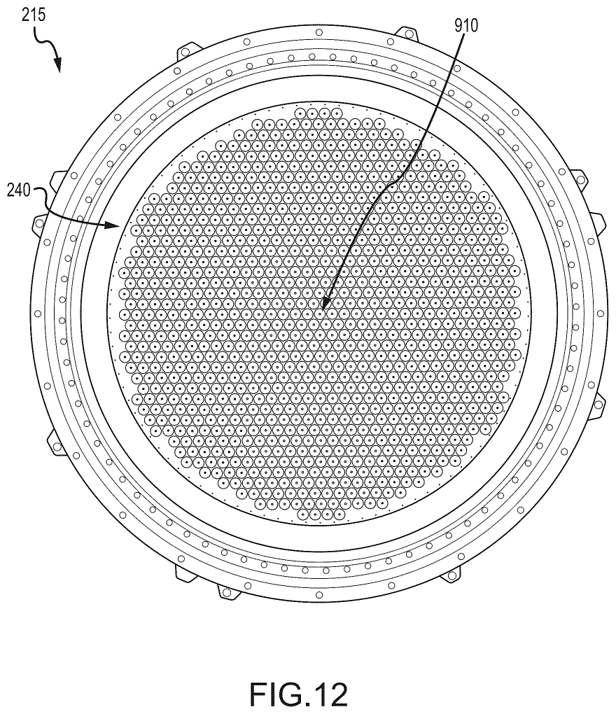

In yet another embodiment, and referring to FIGS. 9-12, the center region 300 may comprise a plurality of third through-holes 920 and a plurality of fourth through-holes 905. The outer region 305 may comprise a plurality of fifth through-holes 925. For example, the center region 300 may comprise 12 third through-holes 920 and 6 fourth through-holes 905. The center region 300 may further comprise at least one sixth through-hole 900. In the present embodiment, the center region 300 has a maximum width in a range of 30 mm to 60 mm. For example, the distance between opposing third through-holes 920 may be approximately 40 mm.

In the present embodiment, each through-hole 920 from the plurality of third through-holes may comprise an inlet, having a conical shape, at the first surface 235 and an outlet, having a conical shape, at the second surface 240. In the present embodiment, a maximum diameter DI₅ of the inlet may be smaller than a maximum diameter DO₅ of the outlet.

In the present embodiment, each through-hole 905 from the plurality of fourth through-holes may comprise an inlet, having a tube shape, at the first surface 235 and an outlet, having a conical shape, at the second surface 240. Each through-hole 905 comprises a channel 1100 having a length that extends from the inlet to the outlet and has a uniform diameter along the length. For example, the channel 1100 may have a diameter in a range of 1.0 mm to 1.1 mm. In an exemplary embodiment, the diameter is 1.04 mm. In addition, the channel 1100 may be angled relative to the vertical axis Z, and angled inward toward a center of the showerhead plate 215.

In the present embodiment, the sixth through-hole 900 may comprise an inlet, having a tube shape, at the first surface 235 and an outlet 910, having a conical shape, at the second surface 240. The sixth through-hole 900 comprises a channel 930 having a length that extends from the inlet to the outlet 910 and has a uniform diameter along the length. For example, the channel 930 may have a diameter in a range of 1.0 mm to 1.2 mm. In an exemplary embodiment, the diameter is 1.0 mm. The outlet 910 of the sixth through-hole 900 may be located at a geometric center of the showerhead plate 215. The channel 930 is angled relative to the vertical axis Z, and angled inward toward and connected to the outlet 910.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A showerhead plate, comprising:
a top surface and an opposing, bottom surface;
a center region located at a geometric center of the showerhead plate, wherein the center region has a diameter in a range of 10 mm to 60 mm;
an outer region surrounding the center region and extending to an outer edge of the showerhead plate;
a plurality of first through-holes located within the center region and extending from the top surface to the bottom surface;
a plurality of second through-holes located within the outer region and extending from the top surface to the bottom surface;
wherein the second through-holes are differently-shaped from the first through-holes.

2. The showerhead plate according to claim 1, wherein each second through-hole comprises a conical-shaped inlet, having first dimensions, at the top surface and a conical-shaped outlet, having the first dimensions, at the bottom surface, and a linear channel connecting the inlet to the outlet.

3. The showerhead plate according to claim 2, wherein the linear channel has a length in a range of 11 mm to 17 mm and a diameter in a range of 0.5 mm to 1.5 mm, and the conical-shaped inlet and outlet have a maximum diameter in a range of 8 mm to 9 mm.

4. The showerhead plate according to claim 1, wherein each first through-hole comprises a first conical-shaped inlet, having first dimensions, at the top surface and a second conical-shaped outlet, having the second dimensions, at the bottom surface, and a linear channel connecting the inlet to the outlet, wherein the first dimensions are different from the second dimensions.

5. The showerhead plate according to claim 4, wherein the linear channel has a length in a range of 4 mm to 6 mm and a diameter in a range of 0.5 mm to 1.5 mm, and the conical-shaped inlet and outlet have a maximum diameter in a range of 8 mm to 9 mm.

6. The showerhead plate according to claim 4, wherein the linear channel has a length in a range of 8 mm to 11 mm and a diameter in a range of 0.5 mm to 1.5 mm, and the conical-shaped inlet and outlet have a maximum diameter in a range of 8 mm to 9 mm.

7. The showerhead plate according to claim 4, wherein the linear channel has a length in a range of 4 mm to 6 mm and a diameter in a range of 0.5 mm to 1.5 mm, and the conical-shaped inlet and outlet have a maximum diameter in a range of 8 mm to 9 mm.

8. The showerhead plate according to claim 4, wherein the linear channel has a length in a range of 4 mm to 6 mm and a diameter in a range of 0.5 mm to 1.5 mm, and the conical-shaped inlet has a first maximum diameter and outlet has a second maximum diameter, wherein the second maximum diameter is larger than the first maximum diameter.

9. The showerhead plate according to claim 8, wherein the plurality of first holes has a number of first holes in a range of 18 to 20.

10. The showerhead plate according to claim 4, wherein the plurality of first holes has a number of first holes in a range of 28-32.

11. A showerhead plate, comprising:
a top surface and an opposing, bottom surface;
a center region located at a geometric center of the showerhead plate, wherein the center region has a diameter in a range of 10 mm to 60 mm;
an outer region surrounding the center region and extending toward an outer edge of the showerhead plate;
a plurality of first through-holes located within the center region and extending from the top surface to the bottom surface, wherein each first through-hole comprises:
a first inlet having a first conical shape and first dimensions, at the top surface;
a first outlet having a second conical shaped and second dimensions, at the bottom surface; and
a first linear channel connecting the first inlet to the first outlet;
wherein the first dimensions are different from the second dimensions;
a plurality of second through-holes located within the outer region and extending from the top surface to the bottom surface, wherein each second through-hole comprises:
a second inlet having the first conical shape and first dimensions, at the top surface;
a second outlet having the first conical shape and first dimensions, at the bottom surface; and
a second linear channel connecting the second inlet to the second outlet.

12. The showerhead plate according to claim 11, wherein the second linear channel has a length in a range of 11 mm to 17 mm and a diameter in a range of 0.5 mm to 1.5 mm, and the second inlet and the second outlet each have a maximum diameter in a range of 8 mm to 9 mm.

13. The showerhead plate according to claim 11, wherein the first linear channel has a length in a range of 4 mm to 6 mm and a diameter in a range of 0.5 mm to 1.5 mm, and the first inlet and the first outlet each have a maximum diameter in a range of 8 mm to 9 mm.

14. The showerhead plate according to claim 11, wherein the first linear channel has a length in a range of 8 mm to 11 mm and a diameter in a range of 0.5 mm to 1.5 mm, and the first inlet and the first outlet each have a maximum diameter in a range of 8 mm to 9 mm.

15. The showerhead plate according to claim 11, wherein the first linear channel has a length in a range of 4 mm to 6 mm and a diameter in a range of 0.5 mm to 1.5 mm, and the first inlet and the first outlet have a maximum diameter in a range of 8 mm to 9 mm.

16. The showerhead plate according to claim 11, wherein the first linear channel has a length in a range of 4 mm to 6 mm and a diameter in a range of 0.5 mm to 1.5 mm, and the conical-shaped inlet has a first maximum diameter and the outlet has a second maximum diameter, wherein the second maximum diameter is larger than the first maximum diameter.

17. The showerhead plate according to claim 11, wherein the plurality of first holes has a number of first holes in a range of 18 to 32.

18. A showerhead assembly, comprising:
a lid comprising a main inlet configured to coupled to a gas source;
a plenum space in communication with the main inlet and defined at least in part by the lid and a showerhead plate, wherein the showerhead plate comprises:
a top surface and an opposing, bottom surface;
a center region located at a geometric center of the showerhead plate, wherein the center region has a diameter in a range of 10 mm to 60 mm;
an outer region surrounding the center region and extending to an outer edge of the showerhead plate;
a plurality of first through-holes located within the center region and extending from the top surface to the bottom surface, wherein each of the first through-holes comprises:
a conical-shaped first inlet;
a conical-shaped first outlet; and
a first linear channel connecting the inlet and the outlet; and
a plurality of second through-holes located within the outer region and extending from the top surface to the bottom surface, wherein each of the second through-holes comprises:
a conical-shaped second inlet;
a conical-shaped second outlet, wherein the second inlet and the second outlet have equal conical dimensions; and
a second linear channel connecting the inlet and the outlet;
wherein the second through-holes are differently-shaped from the first through-holes; and
wherein the second linear channel has a length that is greater than a length of the first linear channel.

19. The showerhead assembly according to claim 18, wherein:
the plurality of first holes has a number of first holes in a range of 18 to 32; and
the first linear channel has a length in a range of 4 mm to 12 mm and the second linear channel has a length in a range of 12 mm to 20 mm.

20. A showerhead assembly, comprising:
a lid comprising a main inlet configured to couple to a gas source;
a plenum space in communication with the main inlet and defined at least in part by the lid and a showerhead plate, wherein the showerhead plate comprises:
a top surface and an opposing, bottom surface;
a center region located at a geometric center of the showerhead plate;
an outer region surrounding the center region and extending to an outer edge of the showerhead plate;
a plurality of first through-holes located within the center region and extending from the top surface to the bottom surface, wherein at least one hole from the plurality of first through-holes comprises an angled channel extending from a first inlet at the top surface to a conical-shaped first outlet at the bottom surface;
and
a plurality of second through-holes located within the outer region and extending from the top surface to the bottom surface, wherein each of the second through-holes comprises:
a conical-shaped second inlet;
a conical-shaped second outlet, wherein the second inlet and the second outlet have equal conical dimensions; and
a second linear channel connecting the inlet and the outlet;
wherein the second through-holes are differently-shaped from the first through-holes.
